(19) United States
(12) Patent Application Publication
(10) Pub. No.: US 2005/0161717 A1
(43) Pub. Date: Jul. 28, 2005

(54) Semiconductor device and method of fabricating the same

(75) Inventors: Ko Nakamura, Kawasaki (JP); Kazuaki Takai, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/036,322

(22) Filed: Jan. 18, 2005

(30) Foreign Application Priority Data
Jan. 28, 2004 (WO) PCT/JP04/00749
Nov. 9, 2004 (JP) 2004-325325

(51) Int. Cl. H01L 29/76

(52) U.S. Cl. 257/295

(57) ABSTRACT

After bottom electrode film is formed, a first ferroelectric film is formed thereon. Then, the first ferroelectric film is allowed to crystallize. Thereafter, a second ferroelectric film is formed on the first ferroelectric film. Next, a top electrode film is formed on the second ferroelectric film, and the second ferroelectric film is allowed to crystallize.

### CROSS-REFERENCE TO RELATED APPLICATIONS

This application is based upon and claims the benefit of priority from the prior International Application No. PCT/JP2004/000749, filed on Jan. 28, 2004 and Japanese Patent Application No. 2004-325325, filed on Nov. 9, 2004, the entire contents of which are incorporated herein by reference.

### BACKGROUND OF THE INVENTION

1. Field of the Invention

The present invention relates to a semiconductor device having a ferroelectric capacitor and a method of fabricating the same, and in particular to a semiconductor device successfully reduced in leakage current, and a method of fabricating the same.

2. Description of the Related Art

With advancement in micronization of ferroelectric memory, there are accelerating trends in downsizing of capacitor area, and in shifting of ferroelectric circuit system from 2T2C system towards 1T1C system. The 2T2C system has two transistors and two capacitors in a single memory cell, whereas the 1T1C system has a single transistor and a single capacitor in a single memory cell.

Reduction in the capacitor area and shifting of the circuit towards 1T1C needs a high reversal polarization charge of a ferroelectric film, so that it is a general practice to use a PZT film as the ferroelectric film. In such trends towards the reduction in the capacitor area and the 1T1C shifting of the circuit, it is also necessary to suppress polarization reversal voltage of the ferroelectric capacitor using the PZT film. The situation promotes thinning of the PZT film.

The thinning of the PZT film, however, results in a larger electric field if applied with voltage at the same level with the previous, and consequently in increase in leakage current. The leakage current is mainly ascribable to voids which reside in the grain boundary.

In a general method of forming the ferroelectric capacitor having the PZT film, formation of a bottom electrode film, formation of a ferroelectric film, crystallization of the ferroelectric film, formation of a top electrode film, and annealing are carried out in this order. In this method, crystal grains of the ferroelectric film are formed during the crystallization thereof, and at the same time the voids generate in the grain boundary. The top electrode film is embedded into the voids during the formation process of the top electrode film, and this thins the effective film thickness, and results in increase in the leakage current.

Reduction in the voids can, therefore, reduce the leakage current to a large degree, and makes it possible to obtain the leakage current low enough for the practical use, even with a small film thickness.

Patent Document 1 (Japanese Patent Application Laid-Open No. Hei 10-321809) discloses a method of forming a ferroelectric capacitor as described below. In the method, first, spin coating, drying and crystallization of a SrBi₂Ta₂O₉ (SBT) film as a ferroelectric film are repeated three times. Then the fourth coating and drying are carried out. The films are then annealed at 600° C. for 5 minutes, to thereby make the SBT films have an amorphous or microcrystalline state. Next, a top electrode film is formed thereon, which is followed by annealing under a pressure-reduced atmosphere for 30 minutes. This method is successful in obtaining a SBT film (ferroelectric film) having a smooth surface.

Patent Document 2 (Japanese Patent Application Laid-Open No. Hei 8-78636) discloses a method of forming a ferroelectric capacitor as described below. In the method, first, formation by spin coating of a (Ba, Sr)TiO₃ (BST) film as a ferroelectric film and succeeding annealing at a low temperature lower than the crystallization temperature are repeated in a plural number of times. Next, a top electrode film is formed thereon. Annealing is then carried out at a temperature not lower than the crystallization temperature.

Patent Document 3 (Japanese Patent Application Laid-Open No. Hei 8-31951) discloses a method in which a PZT film is crystallized, an amorphous SrTiO₃ (STO) film or BST film is formed thereon, and a Pt top electrode is formed, and a method in which a STO film or BST film is crystallized in oxygen, immediately after the formation thereof.

Patent Document 4 (Japanese Patent Application Laid-Open No. 2001-237384) discloses a method aimed at reducing the leakage current, as described in the next. First, a crystallized ferroelectric film having a perovskitic structure is formed on a bottom electrode. Next, on the ferroelectric film, a precursor solution of the ferroelectric film is formed and dried. Next, the stack is annealed at a low temperature not higher than the perovskite crystallization temperature. A top electrode is formed thereon, and the stack is annealed at a high temperature not lower than the perovskite crystallization temperature.

Patent Document 5 (Japanese Patent Application Laid-Open No. 2000-40799) discloses a method of forming a layer containing Pb, Pt and O between a ferroelectric film and a top electrode, for the purpose of suppressing hydrogen degradation of the ferroelectric film due to catalysis of Pt in case that a Pt film is used as the top electrode.

Use of the PZT film in the method described in Patent Document 1 raises a problem due to its low crystallization temperature than that of the SBT film. That is, the annealing at 600° C. for 5 minutes results in growth of huge crystal grains, and this fails in obtaining the amorphous or microcrystalline state, and what is worse, the voids will generate. The method described in Patent Document 1 is, therefore, unsuccessful in reducing the leakage current if applied to the PZT film.

It may otherwise be possible to reduce the voids to thereby lower the leakage current, if the annealing temperature is lowered taking the crystallization temperature of the PZT film into consideration. This, however, raises another problem of lowering in the reversal polarization charge.

Also in the method described in Patent Document 2, immediately before the formation of the top electrode film, the reversal polarization charge of the PZT film degrades after the annealing, even if the annealing temperature is set to the crystallization temperature or above.

Also the method described in Patent Document 3 is unsuccessful in obtaining a satisfactory level of reversal polarization charge.

The method described in Patent Document 4 is successful in lowering the leakage current, but suffers from lowering in the reversal polarization charge and degradation in the imprint characteristics.

The method described in the Patent Document 5 may possibly suppress the hydrogen degradation per se, but is likely to cause peeling-off of the top electrode. It is also not possible to obtain a sufficient level of the reversal polarization charge.

It is therefore an object of the present invention to provide a semiconductor device and a method of fabricating the same, both of which being capable of reducing the leakage current while keeping the reversal polarization charge at a high level.

### SUMMARY OF THE INVENTION

The present inventors have gone through extensive investigations, aiming at solving the above-described problems, and conceived several embodiments of the invention as described in the next.

As a result of earnest studies to solve the above problems, the present inventors have devised various aspects of the invention described below.

In a method of fabricating a semiconductor device according to the present invention, a bottom electrode film is formed, and thereafter an amorphous first ferroelectric film is formed on the bottom electrode film. Next, the first ferroelectric film is allowed to crystallize. Next, on the first ferroelectric film, an amorphous second ferroelectric film is formed. Thereafter on the second ferroelectric film, a Pt-free top electrode film is formed. Then the second ferroelectric film is allowed to crystallize.

According to the above-described fabrication method, there is provided a semiconductor device typically comprises a bottom electrode; a first ferroelectric film formed on the bottom electrode; a second ferroelectric film formed on the first ferroelectric film so as to fill any voids reside on the surface of the first ferroelectric film; and a top electrode formed on the second ferroelectric film. It should be noted that the second ferroelectric film has substantially no voids such as those reside on the surface of the first ferroelectric film.

### BRIEF DESCRIPTION OF THE DRAWINGS

FIG. 1 is a circuit diagram showing a configuration of a memory cell array of a ferroelectric memory (semiconductor device) fabricated by a method according to an embodiment of the present invention;

FIGS. 2A to 2G are schematic sectional views sequentially showing process steps of the method of fabricating the ferroelectric memory according to the embodiment of the present invention;

FIGS. 3A to 3E are schematic sectional views sequentially showing process steps of a method of forming a ferroelectric film 26;

FIG. 4A is a flow chart showing an exemplary method of forming a ferroelectric film and a top electrode film;

FIG. 4B is a flow chart showing another exemplary method of forming a ferroelectric film and a top electrode film;

FIG. 4C is a flow chart showing still another exemplary method of forming a ferroelectric film and a top electrode film;

FIG. 5A is a graph showing reversal polarization charge;

FIG. 5B is a graph showing leakage current;

FIG. 6 is a chart showing results of a third experiment;

FIG. 7 is a chart showing results of a fourth experiment;

FIG. 8 is a chart showing results of a fifth experiment;

FIG. 9 is also a chart showing results of a fifth experiment;

FIG. 10 is a graph showing relations between annealing time and in-plane distribution 3σ of reversal polarization charge;

FIG. 11 is a graph showing relations between annealing time and sheet resistance;

FIG. 12 is a graph showing relations between sheet resistance of the reference wafer and in-plane distribution 3σ c of level of reversal polarization charge;

FIG. 13 is a chart showing results of an eighth experiment; and

FIG. 14 is a graph showing relations between resistivity and in-plane distribution 3σ of level of reversal polarization charge.

### DETAILED DESCRIPTION OF THE PREFERRED EMBODIMENTS

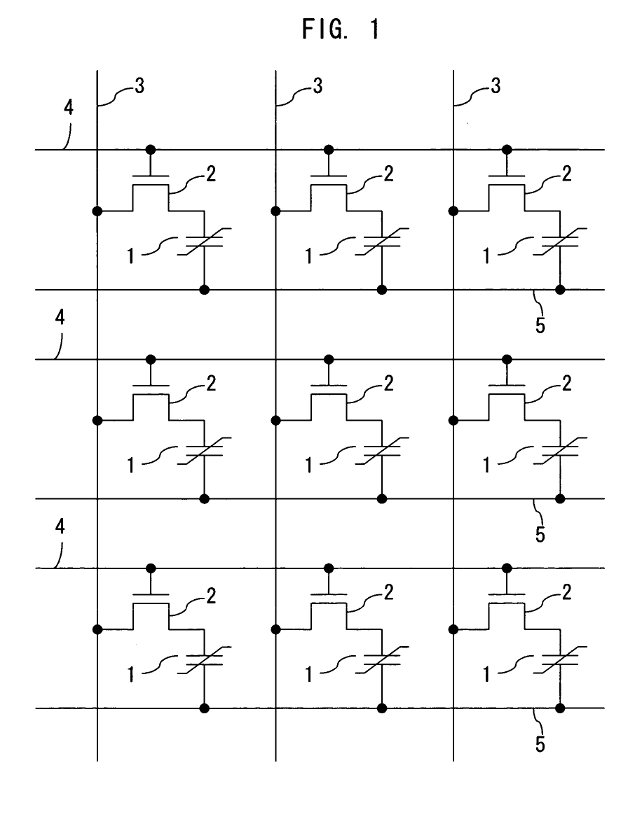

The following paragraphs will specifically describe embodiments of the present invention, referring to the attached drawings. FIG. 1 is a circuit diagram showing a configuration of a memory cell array of a ferroelectric memory (semiconductor device) fabricated by a method according to an embodiment of the present invention.

The memory cell array is provided with a plurality of bit lines extending in one direction, and a plurality of word lines 4 and plate lines 5 extending in the direction normal to the direction in which the bit lines 3 extend. A plurality of memory cells of the ferroelectric memory according to the present embodiment is arranged in an array pattern, so as to be aligned with a lattice composed by the bit lines 3, word lines 4 and plate lines 5. Each memory cell is provided with a ferroelectric capacitor 1 and a MOS transistor 2.

A gate of the MOS transistor 2 is connected to the word line 4. One source/drain of the MOS transistor 2 is connected to the bit line 3, and the other source/drain is connected to one electrode of the ferroelectric capacitor 1. The other electrode of the ferroelectric capacitor 1 is connected to the plate line 5. Each word lines 4 and plate lines 5 are shared by the plurality of MOS transistors 2 arranged in the same direction with that of these lines. Similarly, each bit lines 3 are shared by the plurality of MOS transistors 2 arranged in the same direction therewith. The direction along which the word lines 4 and plate lines 5 extend, and the direction along which the bit lines 3 extend may sometimes be called line direction and row direction, respectively.

In thus-configured memory cell array of the ferroelectric memory, data is stored depending on polarization state of a ferroelectric film provided to the ferroelectric capacitor 1.

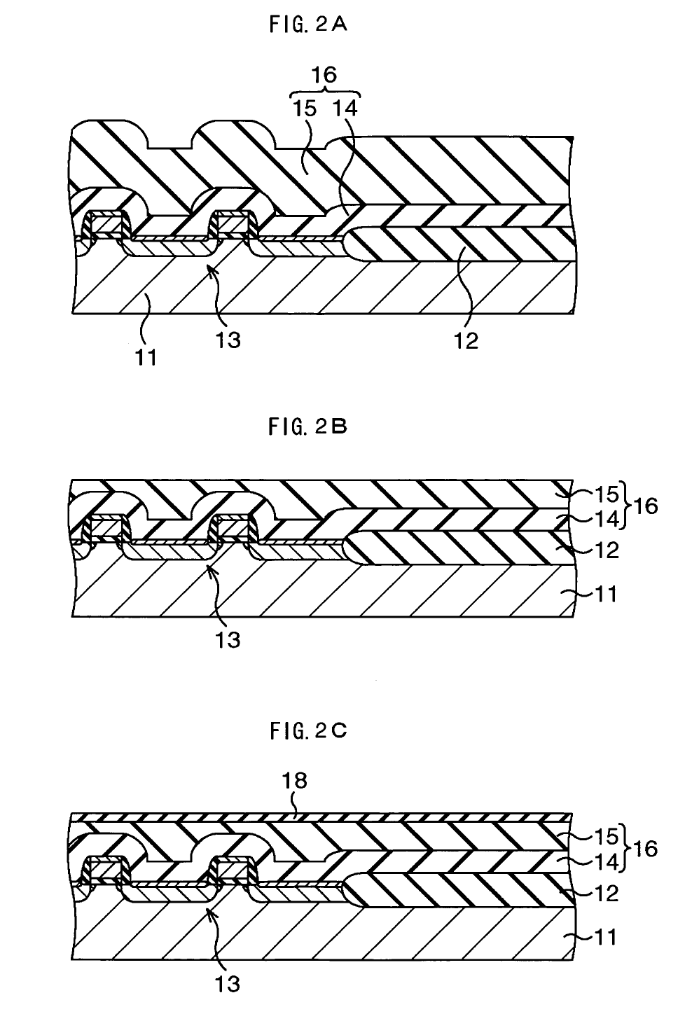

Next paragraphs will describe the method of fabricating the ferroelectric memory (semiconductor device) according to the embodiment of the present invention. It is to be noted herein that sectional structure of each memory cell will be explained together with the method of fabricating thereof for the convenience sake. FIGS. 2A to 2G are schematic sectional views sequentially showing process steps of the method of fabricating the ferroelectric memory according to the embodiment of the present invention.

In the present embodiment, first as shown in FIG. 2A, an element isolation insulating film 12 is formed on the surface of a silicon substrate 11. Next, wells (not shown) are formed in the predetermined regions (transistor-forming regions) by selectively introducing impurities. The conductivity type of the silicon substrate 11 may be either p-type or n-type. Next, a CMOS transistor 13 having an LDD structure is formed in the active region. Thereafter, an anti-oxidative film 14 is formed by a CVD method, so as to cover the CMOS transistor 13. A SiON film of 200 nm thick, for example, is formed as the anti-oxidative film 14. Next, on the anti-oxidative film 14, a SiO₂ film 15 of 600 nm, for example, is formed by a CVD method. The anti-oxidative film 14 and SiO₂ film 15 compose a first interlayer insulating film 16. It is to be noted that the SiO₂ film 15 can be formed by using TEOS (tetraethyl orthosilicate), for example, as a reaction gas.

Next, as shown in FIG. 2B, the SiO₂ film 15 is polished from the top surface thereof by chemical-mechanical polishing (CMP) so as to adjust the thickness of the first interlayer insulating film 16 to 785 nm, for example, measured above the interface with the element isolation insulating film 12 as a baseline. Next, the first interlayer insulating film 16 is thoroughly degassed by annealing in a N₂ atmosphere at 650° C. for 30 minutes.

Thereafter as shown in FIG. 2C, an Al₂O₃ film 18 is formed on the SiO₂ film 15 which functions as an adhesive layer for a bottom electrode, by an RF sputtering method. Thickness of the Al₂O₃ film 18 is adjusted to 20 nm, for example.

Next, as shown in FIG. 2D, a Pt film 25 (bottom electrode film), which serves as a bottom electrode of a ferroelectric capacitor is formed by sputtering on the Al₂O₃ film 18. Thickness of the Pt film 25 is adjusted to 155 nm, for example.

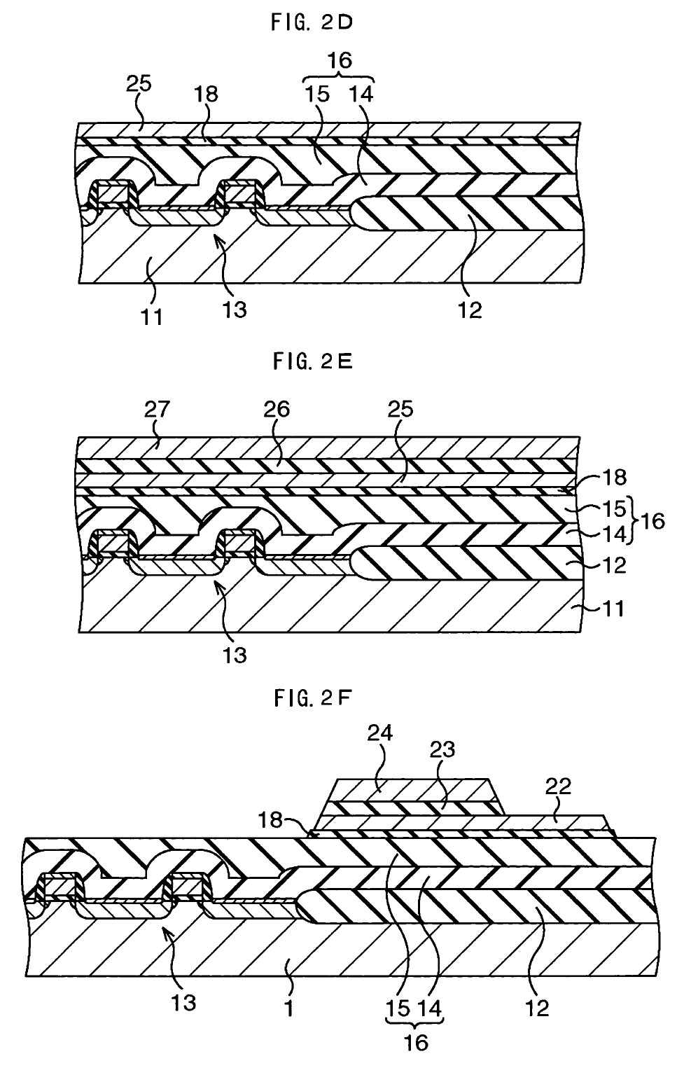

Next, as shown in FIG. 2E, a ferroelectric film 26, which serves as a capacitor insulating film of the ferroelectric capacitor, is formed on the Pt film 25 by an RF sputtering method. Thickness of the ferroelectric film 26 is adjusted to 120 nm, for example. The ferroelectric film 26, herein, is formed as a double-layered film, for example. The fabrication method will be explained below. FIGS. 3A to 3E are schematic sectional views sequentially showing process steps of the method of forming the ferroelectric film 26.

First, on the bottom electrode film 25, an amorphous PZT film 26a of 80 nm thick, for example, is formed by an RF sputtering method. Next, the PZT film 26a is allowed to crystallize by crystallization annealing. This consequently results in formation of crystal grain boundaries 51 in the PZT film 26a, as shown in FIG. 3B. Next, as shown in FIG. 3C, an amorphous PZT film 26b of 40 nm thick, for example, is formed on the PZT film 26a by an RF sputtering method. Then, as shown in FIG. 3D, a top electrode film 27 is formed on the PZT film 26b without causing crystallization of the PZT film 26b. Thereafter, crystallization annealing is effect to thereby allow the PZT film 26b to crystallize. This results in formation of crystal grain boundaries 52 in the PZT film 26b, as shown in FIG. 3E.

The formation of the ferroelectric film 26 is followed by formation of the top electrode film 27 on the ferroelectric film 26, as shown in FIG. 2E. In the formation of the top electrode film 27, formation of a first IrOₓ film is followed by rapid thermal annealing, and is further followed by formation of a second IrO₂ film.

After the second IrO₂ film is formed, a resist pattern having a pattern of a top electrode of the ferroelectric capacitor is formed on the top electrode film 27, and the top electrode film 27 is then etched through the resist pattern as a mask. This consequently results in formation of a top electrode 24 from the top electrode film 27, as shown in FIG. 2F. Next, the resist pattern is removed, and the stack is successively annealed in a furnace. This is a recovery annealing for the purpose of restoring the ferroelectric film 26 from damages caused by the formation of the IrOₓ films. And this annealing contributes to densification of the ferroelectric film 26. After this annealing process, another resist pattern (not shown) having a pattern of a capacitor insulating film of the ferroelectric capacitor is newly formed, and the ferroelectric film 26 is then etched through the resist pattern as a mask. This consequently results in formation of a capacitor insulating film 23 from the ferroelectric film 26, as shown in FIG. 2F. The resist pattern is then removed, and still another resist pattern (not shown) having a pattern of the bottom electrode of the ferroelectric capacitor is newly formed, and the Pt film 25 and the Al₂O₃ film 18 are etched through the resist pattern as a mask. This consequently results in formation of a bottom electrode 22 from the Pt film 25, to thereby obtain the ferroelectric capacitor.

Next, as shown in FIG. 2G, in order to protect the capacitor insulating film 23 composed of PZT, which is susceptible to hydrogen reduction, an Al₂O₃ film is formed as a protective film 19 over the entire surface by a sputtering method. Thickness of the protective film is adjusted to 50 nm, for example. Thereafter, a SiO₂ film 20 is formed as a second interlayer insulating film by a CVD method. Thickness of the SiO₂ film 20 is adjusted to 1500 nm, for example. The SiO₂ film 20 is then planarized by CMP.

Next, contact holes 21 which reach a silicide layer on source/drain diffusion layers of the CMOS transistor 13 are formed in the SiO₂ film 20, protective film 19, SiO₂ film 15 and anti-oxidative film 14, by dry etching through a resist pattern (not shown), having a predetermined pattern, as a mask.

Next, the resist pattern is removed, a Ti film and a TiN film are formed as adhesive layers in the contact holes 21, and a W film is filled therein. These conductive films are subjected to CMP, to thereby leave conductive plugs 28, which are composed of the adhesive layer and W film, only in the contact holes 21.

Next, a contact hole 30 reaching the top electrode 24 and a contact hole 29 reaching the bottom electrode 22 are formed in the SiO₂ film 20 and protective film 19, by dry etching through a resist pattern (not shown), having another predetermined pattern, as a mask.

The resist pattern is removed thereafter, and an Al wiring 31 which includes portions connecting the diffusion layers composing the CMOS transistor 13 and the top electrode 24, for example, is formed on the SiO₂ film 20.

Although not illustrated in the drawings, the process is further followed by formation of an interlayer insulating film, formation of contact plugs, and formation of wirings of the second layer or thereafter. A cover film composed of a TEOS oxide film and a SiN film, for example, is finally formed, to thereby complete the ferroelectric memory having the ferroelectric capacitor.

In the present embodiment, formation of the grain boundary 51 in the PZT film 26a is accompanied by formation of the voids along the grain boundary 51 in the surficial portion of the PZT film 26a. The voids are, however, filled by the PZT film 26b formed thereafter. On the other hand, the PZT film 26b will have substantially no voids formed therein even if the grain boundary 52 is formed, because the crystallization thereof succeeds the formation of the top electrode film 27. This is successful in reducing the leakage current.

It can also suppress lowering in the reversal polarization charge, by allowing the PZT film 26b to crystallize after the formation of the top electrode film 27. The formation of the ferroelectric film 26 using the PZT films 26a and 26b, composed of the same material, is also advantageous in obtaining a high reversal polarization charge. It should be noted, however, that use of a Pt-containing material for the top electrode film 27 will make it more likely to cause the peeling-off, or will make it more difficult to obtain a satisfactory reversal polarization charge, as described above. It is therefore necessary to use a Pt-free material for the top electrode film 27.

In the above-described method, formation of the ferroelectric capacitor having an area in plan view of as small as 2 μm² or around, for example, may sometimes result in a lowered reversal polarization charge in the center portion of a wafer. This may undesirably result in functional failures. In this case, it is preferable to raise a resistivity of a material composing the top electrode film, such as iridium oxide, or to increase a temperature and/or time of the crystallization annealing of the ferroelectric film carried after the formation of the top electrode film.

The resistivity is preferably adjusted so as to have an average value thereof in a range from 350 μΩ·cm to 410 μΩ·cm, for example. Assuming an in-plane variation of a wafer as ±5%, the resistivity falls within a range approximately from 331 μΩ·cm to 431 μΩ·cm. The resistivity of the top electrode film can be raised by increasing a flow rate of oxygen, or by lowering sputtering power in the formation of the top electrode film, for example. The lowering in the sputtering power, however, affects not only the resistivity but also growth rate of the top electrode film, so that increase in the oxygen flow rate is more preferable than lowering in the sputtering power. There may also be a possible case in that the resistivity of the obtained film vary despite no changes are made on any conditions, if the apparatus, target or the like used therefor are changed. Also in this case, it is preferable to adjust the oxygen flow rate and/or sputtering power.

As for conditions for the crystallization annealing, it is preferable to adjust the annealing time to 120 seconds or more under an annealing temperature of 725° C., and to 20 seconds or more under an annealing temperautre of 750° C., for example. Generally saying, as detailed below (see seventh experiment), it is preferable to carry out the crystallization annealing under a condition (combination of temperature and annealing time, for example) capable of achieving heat energy with which, after a rapid thermal annealing in a face-down manner in an Ar atmosphere is conducted to a reference wafer fabricated as described below is, the sheet resistance of the front surface of the reference wafer becomes 1218 Ω/□ or below. The reference wafer used herein is fabricated by implanting B⁺ ion into a Si wafer from a direction expressed by a twist angle of 0° and tilt angle of 7° under an acceleration voltage of 50 keV and a dose of 1×10¹⁴ atoms/cm², and then by sequentially forming a Ti film of 20 nm thick and a Pt film of 180 nm thick on the back surface of the Si wafer, wherein the Si wafer has an N-type conductivity, a surface crystal orientation of (100), and a resistivity of 4±1 Ω·cm.

Formation of the ferroelectric capacitor under these conditions makes it possible to suppress in-wafer variation in the reversal polarization charge, and to obtain the semiconductor device having desired characteristics with a higher yield ratio.

It should be noted that a material composing the ferroelectric film is by no means limited to PZT, but also may be PZT doped with Ca, Sr, La, Nb, Ta, Ir and/or W, for example. Besides the PZT-base film, it is also allowable to form an SBT-base film or Bi-layer-structured compound system film. It is still also allowable to make the first ferroelectric film and second ferroelectric film using different materials from each other.

The cell structure of the ferroelectric memory is not limited to 1T1C system, but also may be 2T2C system.

### EXPERIMENTS

The following paragraphs will describe results of the experiments actually conducted by the present inventors.

### First Experiment

In a first experiment, a SiO₂ film of 100 nm thick was formed on the surface of a Si substrate by thermal oxidation. Next, an Al₂O₃ film of 20 nm thick was formed on the SiO₂ film by a sputtering method using an Al₂O₃ target. Sputtering conditions include power: 2 kW, Ar flow rate: 20 sccm, temperature: room temperature, and film-growth time: 34 seconds. Next, a Pt film of 155 nm thick was formed on the Al₂O₃ film by a sputtering method using a Pt target. Sputtering conditions include power: 1 kW, Ar flow rate: 116 sccm, temperature: 350° C., and film-growth time: 93 seconds. The Pt film was thus formed as a bottom electrode film.

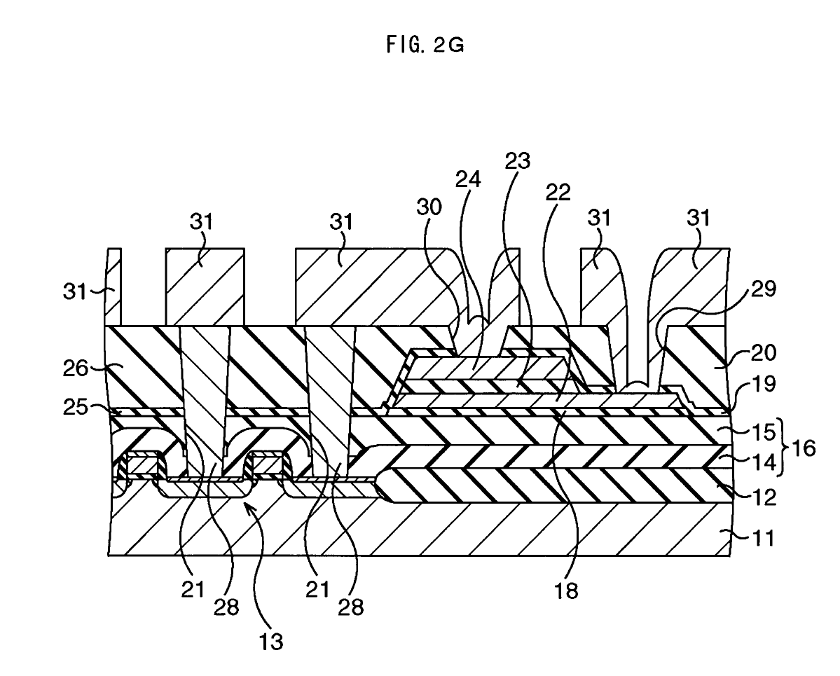

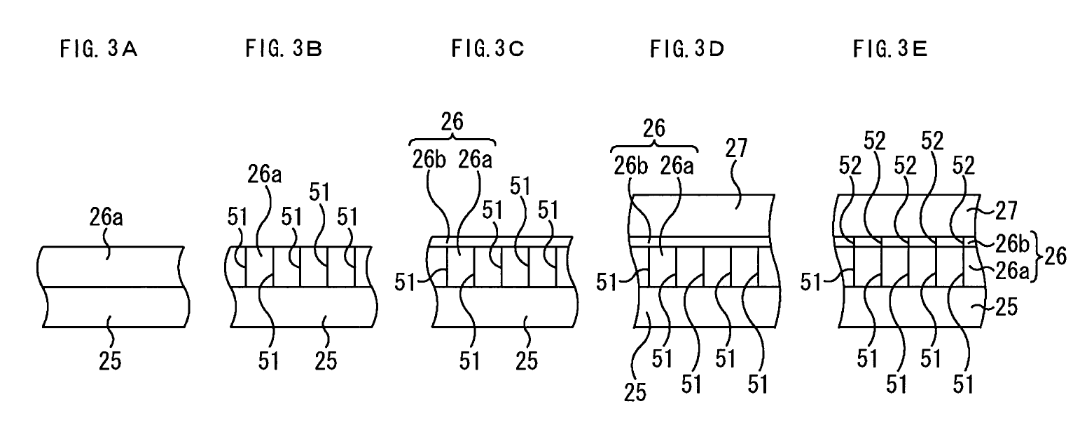

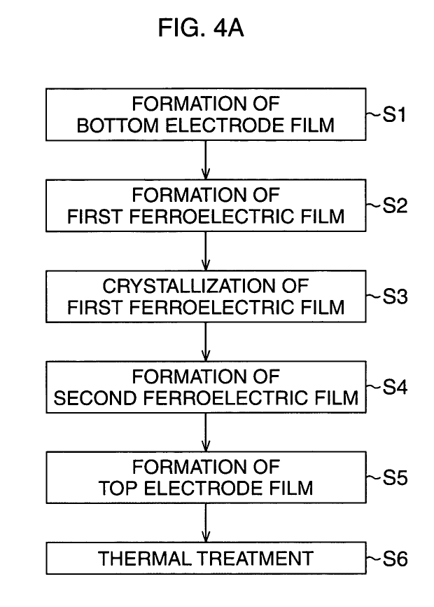

Next, the ferroelectric film and top electrode film were formed based on three methods shown in FIGS. 4A to 4C. FIG. 4A is a flow chart showing an exemplary method according to the embodiment of the present invention, FIG. 4B is a flow chart showing a method according to a first comparative example, and FIG. 4C is a flow chart showing a method according to a second comparative example. The first comparative example herein corresponds to a conventional method.

In the example of the present invention, as shown in FIG. 4A, the bottom electrode film was formed as described above (step S1), a first PZT film (a film corresponded to the PZT film 26a ) was formed by a sputtering method using a PZT target (step S2). Sputtering conditions include power: 1 kW, Ar flow rate: 20 sccm, temperature: 50° C., and film-growth time: 214 seconds. Thickness of the thus-obtained first PZT film was found to be 130 nm, and a Pb content was 1.13. The Pb content herein relates to compositional ratios of Pb, Zr and Ti, and is expressed by amount (ratio) of Pb assuming the total of Zr and Ti as 1.

Next, the first PZT film was crystallized using a rapid thermal annealing apparatus (step S3). Annealing conditions herein include temperature: 585° C., Ar flow rate: 1.975 slm, O₂ flow rate: 25 sccm, and heating time: 90 seconds.

Next, a second PZT film (a film corresponds to the PZT film 26b ) was formed on the first PZT film by a sputtering method using a PZT target (step 4). Sputtering conditions herein include power: 1 kW, Ar flow rate: 20 sccm, temperature: 50° C., and film-growth time: 33 seconds. Thickness of the thus-obtained second PZT film was found to be 20 nm, and the Pb content was 1.24.

An IrO₂ film was then formed as a top electrode film on the second PZT film by a sputtering method using an Ir target (step S5). Sputtering conditions herein include power: 2 kW, Ar flow rate: 100 sccm, O₂ flow rate: 56 sccm, temperature: 20° C., and film-growth time: 9 seconds. Thickness of the thus-obtained IrO₂ film was found to be 47 nm.

Next, the second PZT film was crystallized using a rapid thermal annealing apparatus (step S6). Annealing conditions herein include temperature: 725° C., Ar flow rate: 2 slm, O₂ flow rate: 20 sccm, and annealing time: 20 seconds.

In the first comparative example (conventional example), as shown in FIG. 4B, a bottom electrode film was formed as described above (step S11), and a PZT film was formed on the bottom electrode film by a sputtering method using a PZT target (step S12). Sputtering conditions herein include power: 1 kW, Ar flow rate: 20 sccm, temperature: 50° C., and film-growth time: 247 seconds. Thickness of the thus-obtained PZT film was found to be 150 nm, and the Pb content was 1.13.

Next, the PZT film was crystallized using a rapid thermal annealing apparatus (step S13). Annealing conditions herein include temperature: 585° C., Ar flow rate: 1.975 slm, O₂ flow rate: 25 sccm, and annealing time: 90 seconds.

Next, an IrO₂ film was formed on the PZT film as a top electrode film by a sputtering method using an Ir target (step S14). Sputtering conditions herein include power: 2 kW, Ar flow rate: 100 sccm, O₂ flow rate: 56 sccm, temperature: 20° C., and film-growth time: 9 seconds. Thickness of the thus-obtained IrO₂ film was found to be 47 nm.

The PZT film was then completely crystallized by annealing using a rapid thermal annealing apparatus (step S15). Annealing conditions herein include temperature: 725° C., Ar flow rate: 2 slm, O₂ flow rate: 20 sccm, and heating time: 20 seconds.

In the second comparative example, as shown in FIG. 4C, a bottom electrode film was formed as described above (step S21), and a first PZT film was formed on the bottom electrode film by a sputtering method using a PZT target (step S22). Sputtering conditions herein include power: 1 kW, Ar flow rate: 20 sccm, temperature: 50° C., and film-growth time: 214 seconds. Thickness of the thus-obtained first PZT film was found to be 130 nm, and the Pb content was 1.13.

Next, a first PZT film was crystallized using a rapid thermal annealing apparatus (step S23). Annealing conditions herein include temperature: 585° C., Ar flow rate: 1.975 slm, O₂ flow rate: 25 sccm, and annealing time: 90 seconds.

Next, a second PZT film (a film corresponds to the PZT film 26b) was formed on the first PZT film by a sputtering method using a PZT target (step S24). Sputtering conditions herein include power: 1 kW, Ar flow rate: 20 sccm, temperature: 50° C., and film-growth time: 33 seconds. Thickness of the thus-obtained second PZT film was found to be 20 nm, and the Pb content was 1.24.

The second PZT film was then crystallized (step S25). Annealing conditions herein include temperature: 585° C., Ar flow rate: 1.975 slm, O₂ flow rate: 25 sccm, and annealing time: 90 seconds.

Next, an IrO₂ film was formed as a top electrode film on the second PZT film by a sputtering method using an Ir target (step S26). Sputtering conditions herein include power: 2 kW, Ar flow rate: 100 sccm, O₂ flow rate: 56 sccm, temperature: 20° C., and film-growth time: 9 seconds. Thickness of the thus-obtained IrO₂ film was found to be 47 nm.

The second PZT film was then crystallized by annealing using a rapid thermal annealing apparatus (step S27). Annealing conditions herein include temperature: 725° C., Ar flow rate: 2 slm, O₂ flow rate: 20 sccm, and annealing time: 20 seconds.

After three types of ferroelectric capacitors were thus formed, the reversal polarization charge and leakage current of the each ferroelectric capacitors were measured. The reversal polarization charge was measured under a voltage of 3 V applied between the top electrode film and the bottom electrode film, and the leakage current was measured under a voltage of 5 V applied between the top electrode film and the bottom electrode film. Results are shown in Table 1.

TABLE 1

| | reversal | |
|---|---|---|
| | polarization | Leakage |
| | charge (3 V) | current (5 V) |
| Embodiment | 22 μC/cm² | 4.3 × 10⁻¹⁰ A |
| First comparative example | 22 μC/cm² | 2.2 × 10⁻⁸ A |
| (conventional example) | | |
| Second comparative example | 19 μC/cm² | 4.3 × 10⁻¹⁰ A |

As shown in Table 1, the embodiment of the present invention was successful in reducing the leakage current by two orders of magnitude or around, as compared with the first comparative example, which corresponds to the conventional examples, while keeping a high reversal polarization charge. On the other hand, the second comparative example was successful in reducing the leakage current as compared with the first comparative example, but was undesirably lowered in the reversal polarization charge by 3 μC/cm².

### Second Experiment

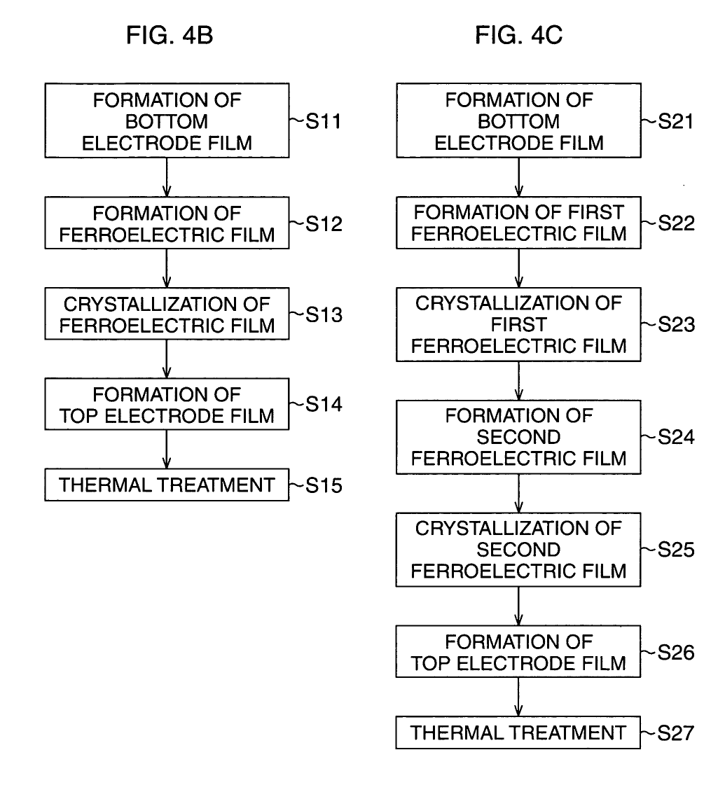

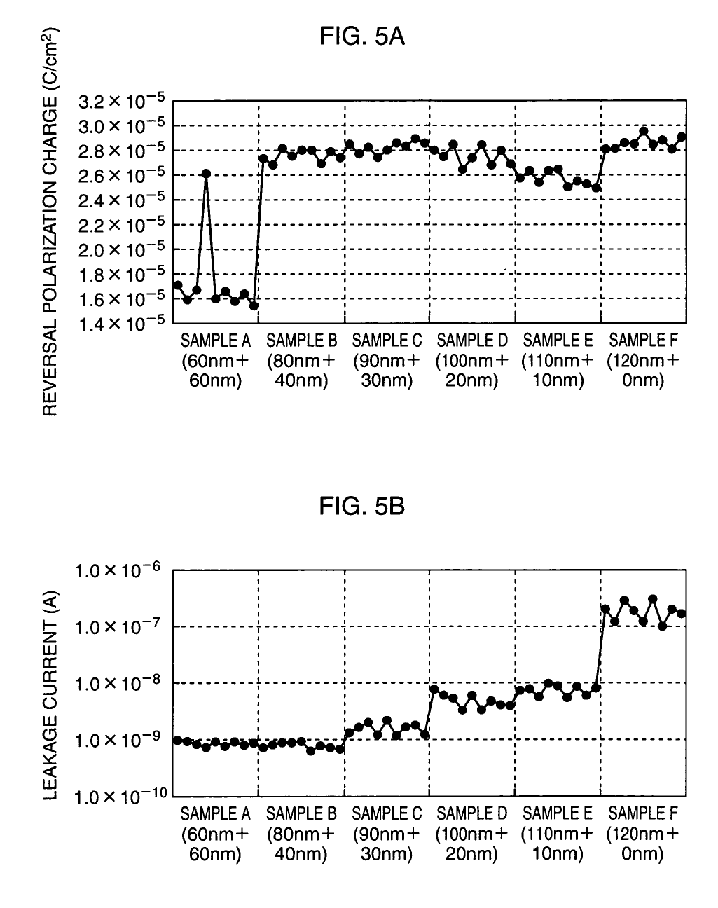

In the second experiment, various ferroelectric capacitors were fabricated following the method shown in FIG. 4A, under varied thickness of the first PZT film and second PZT film. The thicknesses of each of the first and second PZT films were adjusted by varying the film-growth time, and the total film thickness was fixed to 120 nm. The reversal polarization charge and leakage current were measured similarly to as described in the first experiment. Results were shown in FIG. 5A and FIG. 5.

As shown in FIG. 5A and FIG. 5B, Sample A having a thickness of the first PZT film of 60 nm and a thickness of the second PZT film of 60 nm was successfully low in the leakage current, but was extremely low in the reversal polarization charge. Sample F having a thickness of the first PZT film of 120 nm but has no second PZT film was high in the reversal polarization charge, but was also high in the leakage current. In contrast to these, Sample B having a thickness of the first PZT film of 80 nm and a thickness of the second PZT film of 40 nm, Sample C having a thickness of the first PZT film of 90 nm and a thickness of the second PZT film of 30 nm, Sample D having a thickness of the first PZT film of 100 nm and a thickness of the second PZT film of 20 nm, and Sample E having a thickness of the first PZT film of 110 nm and a thickness of the second PZT film of 10 nm were successful in obtaining high reversal polarization charge, and were low in the leakage current.

It is supposed from the results that the first PZT film (first ferroelectric film) having a thickness smaller than that of the second PZT film results in sharp decrease in the reversal polarization charge, and conversely the second PZT film having a thickness as small as 50% of less of that of the first PZT film is successful in obtaining a high reversal polarization charge. It is therefore preferable that the thickness of the second ferroelectric film is adjusted to 50% or less of that of the first ferroelectric film. It is also supposed that a larger thickness of the second PZT film (second ferroelectric film) results in a lower leakage current.

### Third Experiment

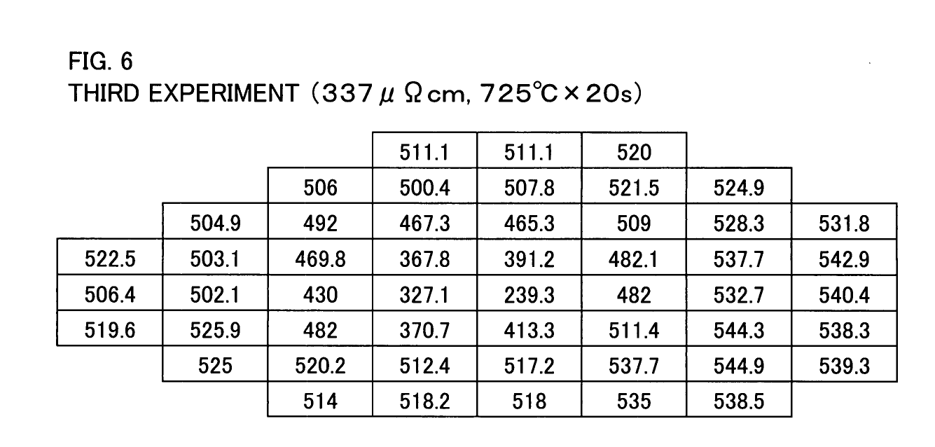

In the third experiment, ferroelectric capacitors were fabricated following the method shown in FIG. 4A. In step S5, an IrO₂ film having an in-plane average resistivity of 337 μΩ·cm was formed as the top electrode film. In step S6, annealing was carried out at 725° C. for 20 seconds. Planar geometry of the ferroelectric capacitors was a 1.15 μm×1.8 μm rectangle. In-plane distribution of the reversal polarization charge was measured. Results are shown in FIG. 6. The bottom edge of FIG. 6 falls on the orientation flat. The same will apply also to the in-plane distribution charts described hereinafter.

As shown in FIG. 6, areas low in the reversal polarization charge were found to concentrate in the center portion of the wafer. Difference between the maximum value (544.9 fC/cell) and minimum value (239.3 fC/cell) of the reversal polarization charge was found to be approximately 306 fC/cell. Distribution 3σ was as large as 182 fC/cell.

### Fourth Experiment

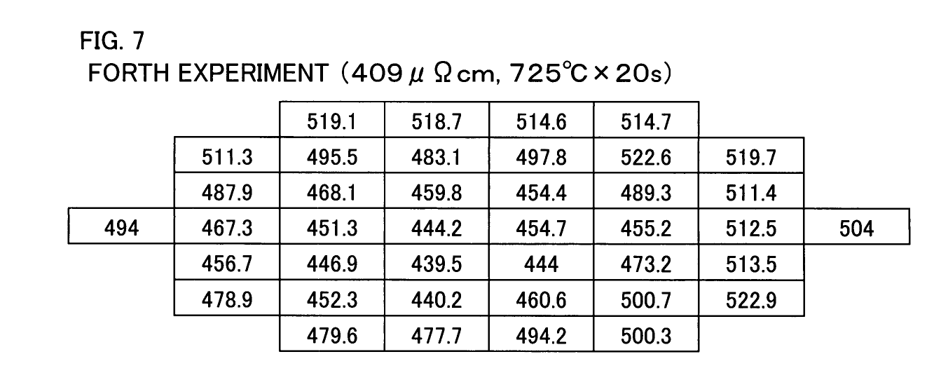

Also in the fourth experiment, ferroelectric capacitors were fabricated following the method shown in FIG. 4A. In step S5, an IrO₂ film having an in-plane average resistivity of 409 μΩ·cm was formed as the top electrode film, by sputtering using a DC sputtering apparatus, under conditions of output power: 2 kW, Ar flow rate: 100 sccm, O₂ flow rate: 60 sccm, film-growth temperature: 20° C., and film-growth time: 9 seconds. In step S6, annealing was carried out at 725° C. for 20 seconds. Planar geometry of the ferroelectric capacitors was a 1.15 μm×1.8 μm rectangle. In-plane distribution of the reversal polarization charge was measured. Results are shown in FIG. 7.

As shown in FIG. 7, it was found that the reversal polarization charge elevated in the center portion of the wafer as compared with the results shown in FIG. 6, and decreased in the peripheral portion. This successfully raised the in-plane uniformity in the reversal polarization charge. More specifically, difference between the maximum value (522.9 fC/cell) and minimum value (439.5 fC/cell) of the reversal polarization charge was reduced to as small as approximately 83 fC/cell, and distribution 3σ was also lowered to as low as 81 fC/cell.

### Fifth Experiment

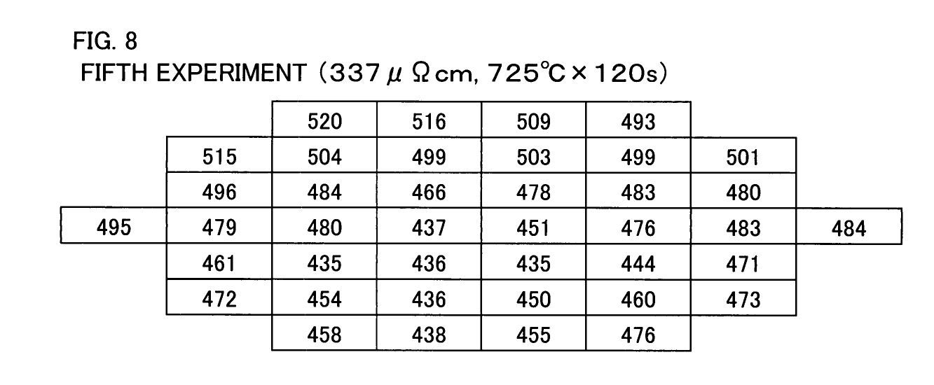

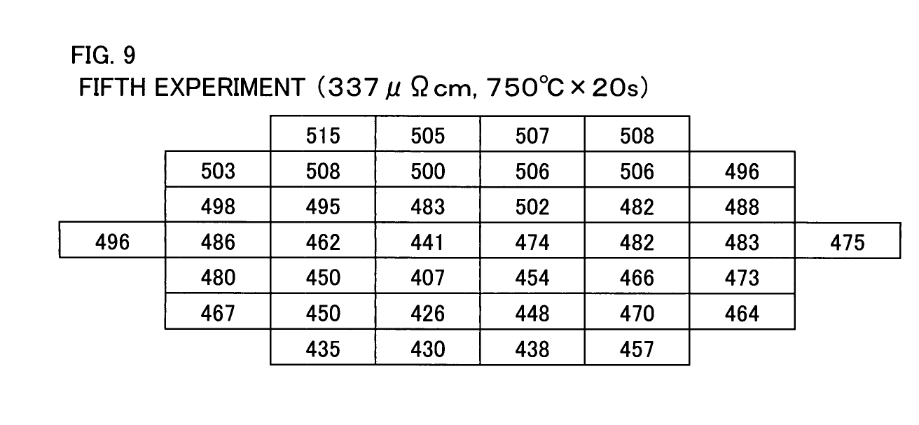

Also in the fifth experiment, two types of ferroelectric capacitor were fabricated following the method shown in FIG. 4A, while varying the annealing conditions in step S6. Annealing conditions were set for one capacitor as temperature: 725° C. and annealing time: 120 seconds, and were set for the other as temperature: 750° C. and annealing time: 20 seconds. In step S5, the IrO₂ film having an in-plane average resistivity of 337 μΩ·cm was formed as the top electrode film. Planar geometry of the ferroelectric capacitors was a 1.15 μm×1.8 μm rectangle. In-plane distribution 3σ of the reversal polarization charge was measured. Results are shown in FIG. 8 and FIG. 9, respectively in this order.

As shown in FIG. 8, the annealing conditions of temperature: 725° C. and annealing time: 120 seconds resulted in increase in the reversal polarization charge in the center portion of the wafer, and in lowering in the peripheral portion, as compared with the results shown in FIG. 6. This resulted in improvement in the uniformity of the in-plane distribution of the reversal polarization charge. More specifically, difference between the maximum value (520 fC/cell) and minimum value (435 fC/cell) was reduced to as low as 85 fC/cell, and the distribution 3σ was also lowered to as low as 75 fC/cell.

Similarly, as shown in FIG. 9, the annealing conditions of temperature: 750° C. and annealing time: 20 seconds also resulted in increase in the reversal polarization charge in the center portion of the wafer, and in lowering in the peripheral portion, as compared with the results shown in FIG. 6. This resulted in improvement in the uniformity of the in-plane distribution of the reversal polarization charge. More specifically, difference between the maximum value (515 fC/cell) and minimum value (407 fC/cell) was reduced to as low as 108 fC/cell, and the distribution 3σ was also lowered to as low as 81 fC/cell.

### Sixth Experiment

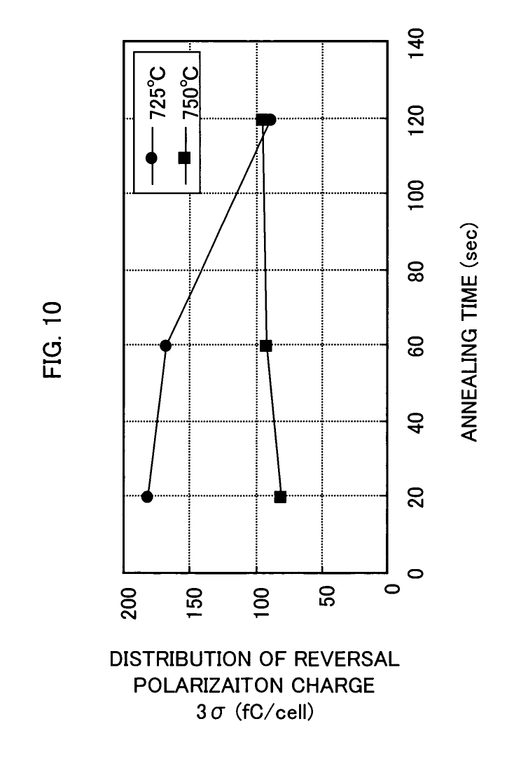

In the sixth experiment, six types of ferroelectric capacitor were fabricated following the method shown in FIG. 4A, while varying the annealing conditions in step S6. The annealing temperature was set to 725° C. or 750° C., and the annealing time was set to 20 seconds, 60 seconds or 120 seconds. In step S5, an IrO₂ film having an in-plane average resistivity of 337 μΩ·cm was formed as the top electrode film. Planar geometry of the ferroelectric capacitors was a 1.15 μm×1.8 μm rectangle. In-plane distribution 3σ of the reversal polarization charge was measured. Results are shown in FIG. 10.

As shown in FIG. 10, the annealing temperature of 725° C. resulted in a large variation in the distribution 3σ depending on the annealing time, and it was supposed that the annealing has to be continued for 120 seconds or more in order to suppress the distribution 3σ to a desirable value of 100 fC/cell or below. On the other hand, the annealing temperature of 750° C. was successful in suppressing the distribution 3σ to 100 fC/cell or below irrespective of the annealing time, but 20 seconds or more.

Therefore in the annealing in step S6, it can be said that a sufficient energy of heat can be given to the ferroelectric capacitor, and the uniformity in the in-plane distribution of the reversal polarization charge can further be improved, if the annealing time is set to 120 seconds or more under the annealing temperature set to 725° C., and if the annealing temperature is set to 20 seconds or more under the annealing temperature set to 750° C.

### Seventh Experiment

In the seventh experiment, experiments and discussions were made for the purpose of generalizing the ranges of the temperature and annealing time obtained in the sixth experiment.

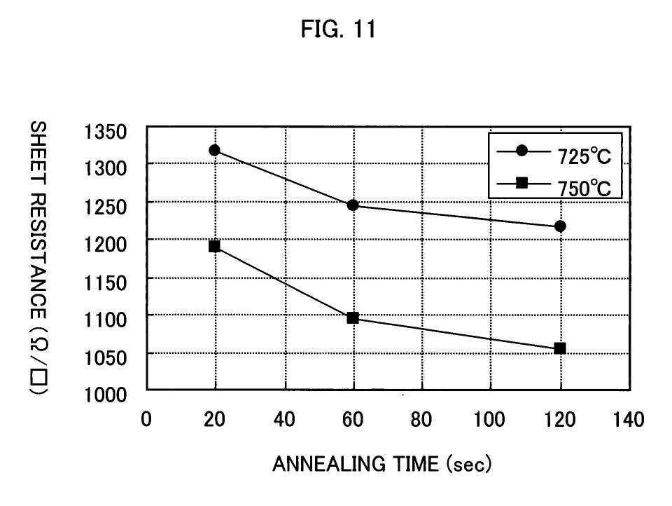

First, a Si wafer having a conductivity type of N-type, a surface crystal orientation of (100), and a resistivity of 4±1 Ω·cm was obtained. Next, B⁺ ion was implanted into the Si wafer from a direction expressed by a twist angle of 0° and tilt angle of 7°, under an acceleration voltage of 50 keV and a dose of 1×10¹⁴ atoms/cm². Next, a Ti film of 20 nm thick and a Pt film of 180 nm thick were sequentially formed on the back surface of the Si wafer, to thereby fabricate a reference wafer. The reference wafer is then subjected to rapid thermal annealing in a face-down manner, or by keeping the front back having the Pt film formed thereon upward, in an Ar atmosphere. The rapid thermal annealing was carried out under conditions of an annealing temperature of 725° C. or 750° C., and annealing time of 20 seconds, 60 seconds or 120 seconds, similarly to as described in the sixth experiment. Sheet resistances of each sample were measured. Maximum sheet resistances of each sample were shown in FIG. 11.

As shown in FIG. 11, a lower energy of annealing resulted in a higher sheet resistance. In other words, the lower and the shorter the annealing temperature and annealing time became, the smaller the energy given to the wafer became, and the higher the sheet resistance became.

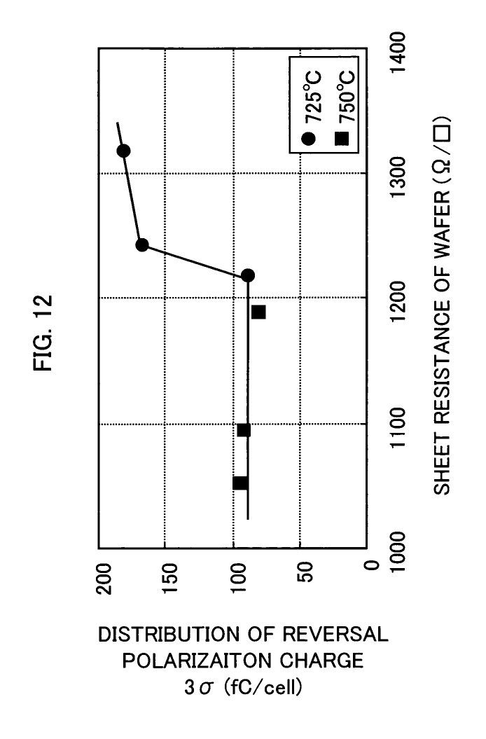

FIG. 12 shows relations between sheet resistance of the reference wafer and in-plane distribution 3σ of the reversal polarization charge. It should be noted that the sheet resistance of the reference wafer is obtained by a measurement carried out after the annealing in Ar, and the in-plane distribution 3σ of the reversal polarization charge is obtained by a measurement carried out after the annealing in a mixed gas of Ar gas and O₂ gas. Therefore, the atmospheres differed from each other. The difference is, however, not affective to the energy of heat.

As shown in FIG. 12, the in-plane distribution 3σ of the reversal polarization charge became minimum and constant at a sheet resistance of 1218 Ω/□ or below. It can therefore be said that an in-plane distribution 3σ of the reversal polarization charge of 100 fC/cell or below was successfully obtained, by giving the ferroelectric capacitor with an energy of heat capable of adjusting the sheet resistance of the surface of the reference wafer to 1218 Ω/□ or below, in the annealing after the top electrode film was formed.

### Eighth Experiment

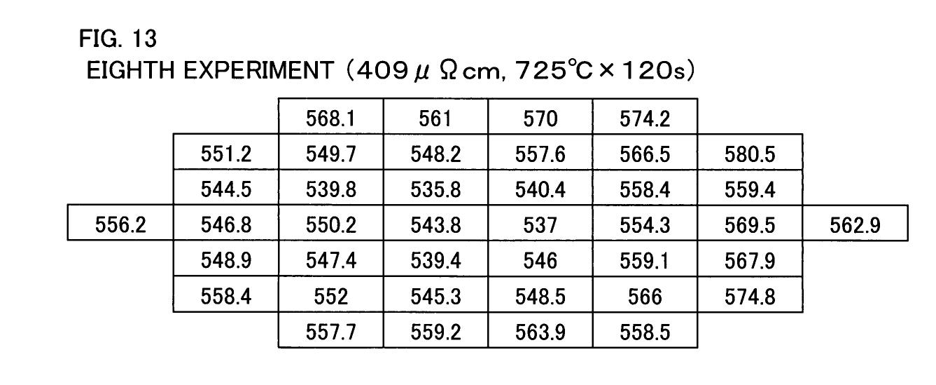

Also in the eighth experiment, the ferroelectric capacitors were fabricated following the method shown in FIG. 4A. In step S5, an IrO₂ film having an in-plane average resistivity of 409 μΩ·cm was formed as the top electrode film, similarly to as described in the fourth experiment. In step S6, annealing was carried out at 725° C. for 120 seconds similarly to as described in the fifth experiment. Planar geometry of the ferroelectric capacitors was a 1.15 μm×1.8 μm rectangle. In-plane distribution of the reversal polarization charge was measured. Results are shown in FIG. 13.

As shown in FIG. 13, areas in the center portion of the wafer, having only small reversal polarization charge, were found to almost disappear, and in-plane uniformity in the reversal polarization charge was found to extremely increase. More specifically, difference between the maximum value (580.5 fC/cell) and minimum value (535.8 fC/cell) of the reversal polarization charge was reduced to as small as approximately 45 fC/cell in maximum, and the distribution 3σ was also found to decreased to as small as 33 fC/cell. As is clear from the above, the eighth experiment was successful in further improving the uniformity in distribution as compared not only with the results shown in FIG. 6, but also with the results shown in FIG. 7 and FIG. 8. Also absolute value per se of the reversal polarization charge was also found to increase.

### Ninth Experiment

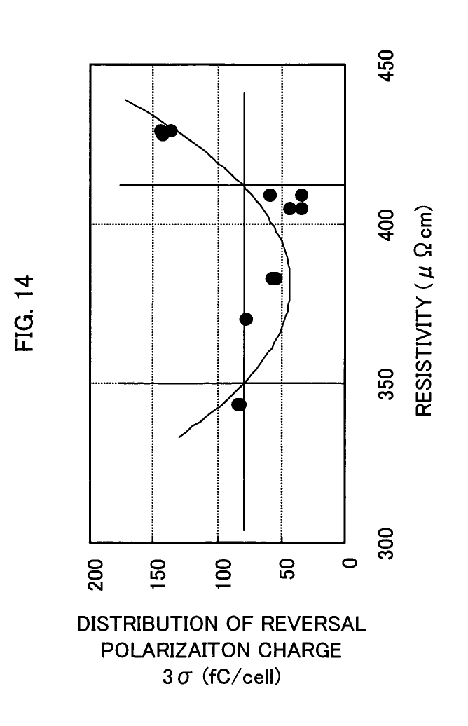

Also in the ninth experiment, the ferroelectric capacitors were fabricated following the method shown in FIG. 4A, while varying the in-plane average resistivity of the top electrode film (IrO₂ film). In step S6, annealing was carried out at 725° C. for 120 seconds similarly to as described in the fifth experiment. Planar geometry of the ferroelectric capacitors was a 1.15 μm×1.8 μm rectangle. Relations between the in-plane average resistivity of the top electrode film and in-plane distribution 3σ of the reversal polarization charge was determined. Results are shown in FIG. 14.

As shown in FIG. 14, the average resistivity was found to fall in a range from 350 to 410 μΩ·cm, and the distribution 3σ of the reversal polarization charge was found to be suppressed to as small as 80 fC/cell or below, proving a good distribution. In-wafer variation in the resistivity in this experiment was found to be ±5%. Considering the in-wafer variation, it is preferable to adjust the resistivity of the top electrode film to fall in a range from 331 to 431 μΩ·cm for every points in the wafer plane.

The present invention makes it possible to reduce the leakage current without causing lowering in the reversal polarization charge.

1. A method of fabricating a semiconductor device comprising:
forming a bottom electrode film;
forming an amorphous first ferroelectric film on said bottom electrode film;
allowing said first ferroelectric film to crystallize;
forming an amorphous second ferroelectric film on said first ferroelectric film;
forming a Pt-free top electrode film on said second ferroelectric film; and
allowing said second ferroelectric film to crystallize.

2. The method of fabricating a semiconductor device according to claim 1, wherein said first ferroelectric film and said second ferroelectric film are formed using the same material.

3. The method of fabricating a semiconductor device according to claim 1, wherein films composed of Pb(Zrₓ, Ti₁₋ₓ)O₃ film (0≦x≦1), or films composed of Pb(Zrₓ, Ti₁₋ₓ)O₃ film and doped with at least any one elements selected from the group consisting of Ca, Sr, La, Nb, Ta, Ir and W are formed as said first and second ferroelectric films.

4. The method of fabricating a semiconductor device according to claim 1, wherein thickness of said second ferroelectric film is set to 50% or less of thickness of said first ferroelectric film.

5. The method of fabricating a semiconductor device according to claim 1, wherein said first and second ferroelectric films are formed by a sputtering method.

6. The method of fabricating a semiconductor device according to claim 1, wherein an iridium oxide film is formed as said top electrode film.

7. The method of fabricating a semiconductor device according to claim 1, wherein films having a perovskite structure after crystallization are formed as said first and second ferroelectric films.

8. The method of fabricating a semiconductor device according to claim 1, wherein a film having an average resistivity of 350 μΩ·cm to 410 μΩ·cm is formed as said top electrode film.

9. The method of fabricating a semiconductor device according to claim 8, wherein a film having resistivity values at each point of 331 μΩ·cm to 431 μΩ·cm is formed as said top electrode film.

10. The method of fabricating a semiconductor device according to claim 1, wherein said step of allowing said second ferroelectric film to crystallize has a step of annealing said second ferroelectric film at 725° C. for 120 seconds or more.

11. The method of fabricating a semiconductor device according to claim 1, wherein said step of allowing said second ferroelectric film to crystallize has a step of annealing said second ferroelectric film at 750° C. for 20 seconds or more.

12. The method of fabricating a semiconductor device according to claim 1, wherein said step of allowing said second ferroelectric film to crystallize has a step of annealing said the second ferroelectric film, under conditions achieving heat energy capable of adjusting sheet resistance of surface of a reference wafer to 1218 Ω/□ or below, after conducting rapid thermal annealing in a face-down manner in an Ar atmosphere, said reference wafer being obtained by implanting B⁺ ion into a Si wafer from a direction expressed by a twist angle of 0° and tilt angle of 7° under an acceleration voltage of 50 keV and a dose of 1×10¹⁴ atoms/cm², and then by sequentially forming a Ti film of 20 nm thick and a Pt film of 180 nm thick on back surface of the Si wafer, said Si wafer having an N-type conductivity, a surface crystal orientation of (100), and a resistivity of 4±1 Ω·cm.

13. A semiconductor device comprising:
a bottom electrode;
a first ferroelectric film formed on said bottom electrode;
a second ferroelectric film formed on said first ferroelectric film so as to fill any voids reside on surface of said first ferroelectric film, said second ferroelectric film having substantially no voids such as those reside on a surface of said first ferroelectric film; and
a top electrode formed on said second ferroelectric film.

14. The semiconductor device according to claim 13, wherein said first and second ferroelectric films are those composed of Pb(Zrₓ, Ti₁₋ₓ)O₃ film (0≦x≦1), or those composed of Pb(Zrₓ, Ti₁₋ₓ)O₃ film and doped with at least any one elements selected from the group consisting of Ca, Sr, La, Nb, Ta, Ir and W.

15. The semiconductor device according to claim 13, wherein thickness of said second ferroelectric film is 50% or less of that of said first ferroelectric film.

16. The semiconductor device according to claim 13, wherein said top electrode is Pt-free.

17. The semiconductor device according to claim 13, wherein said top electrode contains iridium oxide.

18. The semiconductor device according to claim 13, wherein said top electrode film has an average resistivity of 350 μΩ·cm to 410 μΩ·cm.

19. The semiconductor device according to claim 13, wherein said top electrode film has resistivity values at each point of 331 μΩ·cm to 431 μΩ·cm.

20. The semiconductor device according to claim 13, wherein said first and second ferroelectric films after crystallization has a perovskite structure.
